(19) United States
(12) Patent Application Publication
(10) Pub. No.: US 2026/0169134 A1
(43) Pub. Date: Jun. 18, 2026

(54) TRANSMITTING MODULE AND LIDAR

(71) Applicant: SUTENG INNOVATION TECHNOLOGY CO., LTD., Shenzhen (CN)

(72) Inventors: Deguo LI, Shenzhen (CN); Ying LIANG, Shenzhen (CN); Xin ZHAO, Shenzhen (CN); Ruiqi ZHAO, Shenzhen (CN)

(73) Assignee: SUTENG INNOVATION TECHNOLOGY CO., LTD., Shenzhen (CN)

(21) Appl. No.: 19/415,798

(22) Filed: Dec. 11, 2025

(30) Foreign Application Priority Data
Dec. 17, 2024 (CN) 202411865096.8

(51) Int. Cl. G01S 7/481; H05K 1/02; H05K 7/20

(52) U.S. Cl. CPC G01S 7/4814; H05K 1/0206; H05K 1/0271; H05K 7/20445; H05K 2201/066; H05K 2201/068

(57) ABSTRACT

A transmitting module and a LiDAR. The module comprises: a transmitting lens barrel, a transmitting circuit board, a bracket, a heat dissipation housing, and a heat dissipation pad, wherein the transmitting circuit board is located between the transmitting lens barrel and the bracket, and the bracket is located between the transmitting circuit board and the heat dissipation housing; the bracket comprises a first through hole, and the heat dissipation housing comprises a first boss, wherein the first boss passes through the first through hole and abuts against the heat dissipation pad, and the heat dissipation pad is located between the first boss and the transmitting circuit board.

### CROSS-REFERENCE TO RELATED APPLICATION

The present application claims the benefit of priority to Chinese Patent Application No. 202411865096.8, filed on Dec. 17, 2024, which is hereby incorporated by reference in its entirety.

### TECHNICAL FIELD

The present application pertains to the field of LiDAR, and more specifically, to a transmitting module and LiDAR.

### BACKGROUND

LiDAR is a precision instrument utilizing laser pulses for ranging and perception, widely applied in autonomous driving, industrial surveying, robotics, and intelligent transportation systems. Among its components, transmitting units mounted on a transmitting circuit board serve not only as measurement light sources for emitted scanning beams but also as primary heat sources within the LiDAR.

In prior art, thinning the transmitting circuit board is commonly adopted to enhance its heat dissipation. However, excessively thin circuit boards are prone to significant deformation under structural stress, vibration, or temperature variations, adversely affecting the emission direction of scanning beams and operational stability of transmitting units. This consequently degrades LiDAR detection accuracy. Conversely, increasing the thickness of the transmitting circuit board to improve stability compromises its heat dissipation capability.

### SUMMARY

To enhance the operational stability of LiDAR, embodiments of the present application disclose a transmitting module and a LiDAR.

In a first aspect, embodiments of the present application provide a transmitting module including a transmitting lens barrel, a transmitting circuit board, a bracket, a heat dissipation housing, and a heat dissipation pad. The transmitting circuit board is located between the transmitting lens barrel and the bracket, and the bracket is located between the transmitting circuit board and the heat dissipation housing. The bracket includes a first through hole, and the heat dissipation housing includes a first boss. The first boss passes through the first through hole and abuts against the heat dissipation pad, with the heat dissipation pad located between the first boss and the transmitting circuit board.

In some embodiments, the transmitting circuit board includes a first transmitting unit, a second transmitting unit, a first top copper layer, a substrate, and a bottom copper layer. The substrate is located between the first top copper layer and the bottom copper layer, the first top copper layer connects to the first transmitting unit and the second transmitting unit, and the bottom copper layer is located between the substrate and the heat dissipation pad.

The first top copper layer integrates dual functions of electrical conduction and heat transfer, establishing current loops and thermal paths for multiple transmitting units, thereby simplifying the module's structure and reducing manufacturing complexity.

In some embodiments, the transmitting circuit board further includes a plurality of copper columns, and the substrate includes a plurality of second through holes. One of the copper columns is embedded in one of the second through holes.

In some embodiments, one end of each copper column abuts against the first top copper layer, and the other end of each copper column abuts against the bottom copper layer.

The plurality of second through holes penetrating the substrate allows for the embedding of the plurality of copper columns. The copper columns, in turn, establish electrical connection between the first top copper layer and the bottom copper layer. Furthermore, the provision of a plurality of copper columns, compared to a solution with a single copper column, effectively increases the heat dissipation area and enhances the heat dissipation capability of the transmitting circuit board.

In some embodiments, a contact area between the heat dissipation pad and the first boss is greater than or equal to a contact area between the heat dissipation pad and the bottom copper layer.

By configuring the different contact areas, the heat conduction effect between the first boss and the heat dissipation pad is enhanced, thereby improving the heat dissipation performance of the transmitting module.

In some embodiments, a coefficient of thermal expansion of a material of the heat dissipation pad is equal to a coefficient of thermal expansion of a material of the bottom copper layer.

Matching thermal expansion coefficients minimizes differential deformation during temperature changes, preventing delamination at the interface and ensuring stable thermal transfer.

In some embodiments, the bracket includes a support portion, a first upright post, a second upright post, a first reinforcing rib, and a second reinforcing rib. The support portion is located between the heat dissipation housing and the transmitting circuit board. The first upright post is disposed at one end of the support portion, and the second upright post is disposed at the other end of the support portion. The first upright post, the second upright post, the first reinforcing rib, and the second reinforcing rib collectively enclose to form the first through hole.

On one hand, the reinforcing ribs enhance the anti-deformation capability of the bracket, thereby enhancing its support and protection for the transmitting circuit board. On the other hand, the first and second upright posts increase the distance between the two reinforcing ribs and the transmitting circuit board, thereby providing clearance for the electronic components on the circuit board and preventing the reinforcing ribs from pressing against the components during installation.

In some embodiments, a coefficient of thermal expansion of a material of the support portion is equal to a coefficient of thermal expansion of a material of the heat dissipation housing.

Matching thermal expansion coefficients reduces differential deformation between the support portion and housing, maintaining structural integrity under thermal stress.

In some embodiments, the first boss includes a first mounting groove, and the heat dissipation pad is embedded in the first mounting groove.

The groove accommodates thermal expansion stresses, restricts displacement of the pad, and increases contact area with the boss to enhance heat dissipation.

In a second aspect, the application discloses a LiDAR including a receiving module, a processor, and the transmitting module.

The transmitting module integrates electrical and thermal management: conductive elements (first top copper layer, copper columns, bottom copper layer) jointly facilitate electrical current flow and heat dissipation. The bracket provides structural support, mitigating deformation caused by mechanical stress or thermal cycling while distributing heat to the housing. Direct thermal coupling between the first boss and heat dissipation pad via the through hole optimizes heat transfer from critical heat sources.

### BRIEF DESCRIPTION OF DRAWINGS

For a clearer explanation of the technical solutions in the embodiments of the present application, the drawings to be used in the embodiments are briefly described below. It is apparent that the drawings in the following description are only some embodiments of the present application.

FIG. 1 is a schematic structural diagram of a transmitting module according to an embodiment of the present application;

FIG. 2 is a schematic structural diagram of a transmitting lens barrel according to an embodiment of the present application;

FIG. 3 is a schematic structural diagram of a bracket according to an embodiment of the present application;

FIG. 4 is a schematic structural diagram of a transmitting module according to an embodiment of the present application; and

FIG. 5 is a schematic structural diagram of a transmitting module according to an embodiment of the present application.

Reference: 100, transmitting lens barrel; 110, first joint edge; 111, first screw hole; 112, positioning post; 121, first protrusion; 122, second protrusion; 123, third protrusion; 200, transmitting circuit board; 210, substrate; 2211, first top copper layer; 2212, second top copper layer; 2213, third top copper layer; 2214, fourth top copper layer; 2215, fifth top copper layer; 222, copper column; 223, bottom copper layer; 231, first transmitting unit; 232, second transmitting unit; 241, first driving unit; 242, second driving unit; 300, bracket; 310, support portion; 311, third screw hole; 312, second positioning hole; 313, third through hole; 321, first upright post; 322, second upright post; 331, first reinforcing rib; 332, second reinforcing rib; 333, first through hole; 400, heat dissipation housing; 410, first boss; 411, first mounting groove; 500, adhesive layer; 600, heat dissipation pad.

### DETAILED DESCRIPTION

To make the objectives, technical solutions, and advantages of the present application clearer, the embodiments of the present application will be further described in detail below with reference to the accompanying drawings. When the following description refers to the drawings, unless otherwise indicated, the same numerals in different drawings represent the same or similar elements. The implementations described in the following exemplary embodiments do not represent all implementations consistent with the present application. Rather, they are merely examples of structures consistent with some aspects of the present application, as detailed in the appended claims.

In LiDAR systems, the thermal performance of the transmitting module is a critical factor affecting the operational stability of the LiDAR. Among these, transmitting units on the transmitting circuit board generate relatively high peak currents and significant heat during high-power pulsed laser (scanning beam) emission. In practical LiDAR system designs, thinning the transmitting circuit board is commonly adopted to enhance the heat dissipation capability of the transmitting module. However, thinner transmitting circuit boards are prone to deformation under structural stress, vibration, or temperature fluctuations, causing warping (protrusion or depression) at the positions of the transmitting units on the transmitting circuit board. This compromises LiDAR detection accuracy. Conversely, increasing the thickness of the transmitting circuit board to improve operational stability reduces its thermal performance.

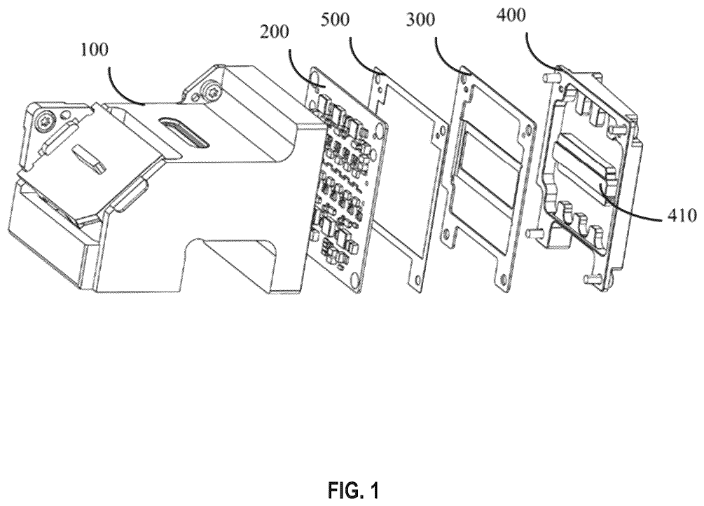

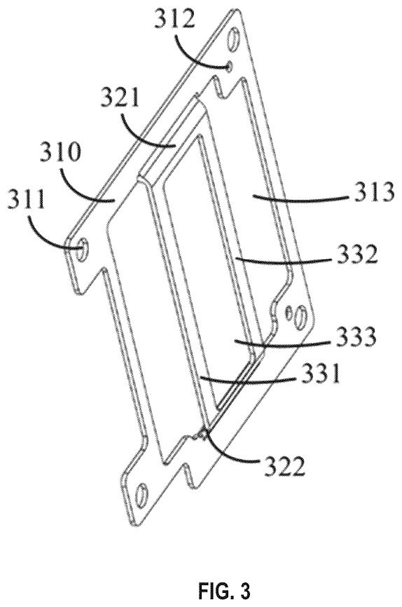

To enhance the operational stability of the LiDAR, the present application discloses a transmitting module with reference to FIGS. 1-5. It simultaneously improves the thermal performance of the transmitting module and the structural stability of the transmitting circuit board, achieving a compatible design of heat dissipation and structural strength.

In one embodiment, as shown in FIG. 1, the transmitting module includes a transmitting lens barrel 100, a transmitting circuit board 200, a bracket 300, a heat dissipation housing 400, and a heat dissipation pad 600. The transmitting circuit board 200 is positioned between the transmitting lens barrel 100 and the bracket 300, while the bracket 300 is located between the transmitting circuit board 200 and the heat dissipation housing 400. The heat dissipation housing 400 includes a first boss 410. The bracket 300 includes a first through hole 333. The first boss 410 passes through the first through hole 333 and abuts the heat dissipation pad 600, while the heat dissipation pad 600 is positioned between the first boss 410 and the transmitting circuit board 200.

In one embodiment, the bracket 300 is first fixedly connected to the transmitting circuit board 200 as an integrated unit before being assembled with other components within the transmitting module (such as the transmitting lens barrel 100 and the heat dissipation housing 400). The fixation methods include one or a combination of adhesive bonding, welding, and threaded connection. The bracket 300 is made from one or a combination of materials such as aluminum alloy, stainless steel, chromium alloy, and plastic. The present application imposes no limitations on the material or manufacturing process of the bracket 300. On one hand, the bracket 300 supports and protects the transmitting circuit board 200, reducing deformation caused by structural stress, vibration, or temperature changes. Leveraging the support and protection provided by the bracket 300 ensures the structural stability of the transmitting circuit board 200, thereby allowing its thickness to be reduced. On the other hand, heat generated by electronic components on the transmitting circuit board 200 (including transmitting units, inductors, capacitors, or driving units) can also be conducted and dispersed to the heat dissipation housing 400 via the bracket 300. This enhances the transmitting circuit board 200′s resistance to deformation while improving its inherent heat dissipation capability.

In one embodiment, an adhesive layer 500 is additionally arranged between the bracket 300 and the transmitting circuit board 200. The bracket 300 and the transmitting circuit board 200 are adhesively fixed via the adhesive layer 500. The adhesive layer 500 strengthens the connection between the bracket 300 and the transmitting circuit board 200, thereby enhancing the support and protection provided by the bracket 300 to the transmitting circuit board 200.

In one embodiment, the side of the transmitting lens barrel 100 facing the transmitting circuit board 200 includes a first joint edge 110. The side of the transmitting circuit board 200 facing the transmitting lens barrel 100 includes a second joint edge. After the transmitting lens barrel 100 and the transmitting circuit board 200 are fixedly installed via screw fastening or adhesive bonding, the first joint edge 110 abuts the second joint edge. The transmitting lens barrel 100 and the bracket 300 cooperatively fix the transmitting circuit board 200.

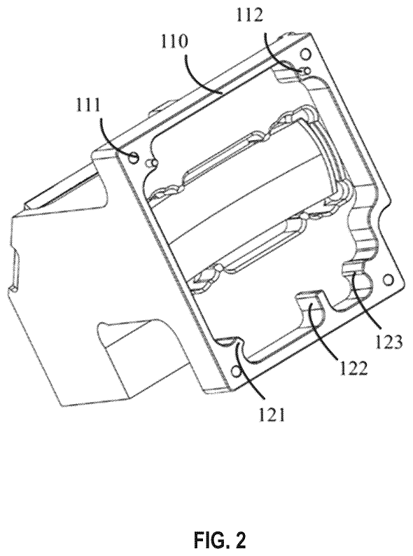

In one embodiment, as shown in FIG. 2, four first screw holes 111 are arranged circumferentially along the first joint edge 110, located at four different positions to disperse structural stress exerted on the transmitting circuit board 200 during screw fastening. The side of the transmitting lens barrel 100 facing the transmitting circuit board 200 further includes protrusions extending towards the internal cavity of the transmitting lens barrel 100. These protrusions include a first protrusion 121, a second protrusion 122, and a third protrusion 123. The first protrusion 121 is adjacent to one first screw hole 111, the third protrusion 123 is adjacent to another first screw hole 111, and the second protrusion 122 is located between the first protrusion 121 and the third protrusion 123. The end face of each protrusion facing the transmitting circuit board 200 lies on the same plane as the end face of the first joint edge 110. The end face of each protrusion facing the transmitting circuit board 200 abuts the second joint edge, increasing the contact area between the transmitting lens barrel 100 and the transmitting circuit board 200. This surface contact configuration allows the first joint edge 110 of the transmitting lens barrel 100 to effectively support the transmitting circuit board 200, minimizing the impact of multi-directional stresses on its deformation.

In one embodiment, the transmitting circuit board 200 includes multiple second screw holes. The bracket 300 includes multiple third screw holes 311. The heat dissipation housing 400 includes multiple fourth screw holes. A locking screw sequentially passes through a fourth screw hole, a third screw hole 311, a second screw hole, and a first screw hole 111 to fixedly connect the heat dissipation housing 400, the bracket 300, the transmitting circuit board 200, and the transmitting lens barrel 100.

In one embodiment, referring to FIGS. 1-3, four first screw holes 111 are circumferentially arranged along the first joint edge 110, and four second screw holes are circumferentially arranged along the second joint edge. The bracket 300 includes four correspondingly arranged third screw holes 311, and the heat dissipation housing 400 includes four correspondingly arranged fourth screw holes. One locking screw sequentially passes through one fourth screw hole, one third screw hole 311, one second screw hole, and one first screw hole 111. In this fixation structure, one locking screw passes through multiple screw holes, enabling the fixed connection of multiple components within the transmitting module. This restricts relative displacement between components while simplifying the structure of the transmitting module.

In one embodiment, referring to FIGS. 1-3, the first joint edge 110 further includes multiple positioning posts 112 extending towards the transmitting circuit board 200. The transmitting circuit board 200 includes multiple first positioning holes. The bracket 300 includes multiple second positioning holes 312. The heat dissipation housing 400 includes multiple third positioning holes. One positioning post 112 sequentially passes through one first positioning hole, one second positioning hole 312, and one third positioning hole.

In one embodiment, the first protrusion 121 is arranged opposite one positioning post 112, and the third protrusion 123 is arranged opposite another positioning post 112. In this fixation structure, one positioning post passes through multiple positioning holes, enabling the alignment of multiple components within the transmitting module. This effectively improves the assembly efficiency and simplifies the structure of the transmitting module.

In one embodiment, with reference to FIGS. 1-5, the bracket 300 includes a support portion 310, a first upright post 321, a second upright post 322, a first reinforcing rib 331, and a second reinforcing rib 332. The support portion 310, first upright post 321, second upright post 322, first reinforcing rib 331, and second reinforcing rib 332 are integrally formed components. Alternatively, the support portion 310, first upright post 321, second upright post 322, first reinforcing rib 331, and second reinforcing rib 332 are separate components connected via one or a combination of screw fastening, welding, adhesive bonding, and snap-fit connection. Among these, the support portion 310 is a plate-like structure, including a third through hole 313. Multiple third screw holes 311 and multiple second positioning holes 312 are circumferentially arranged along the edge of the third through hole 313. The third through hole 313 is used to avoid interference with electronic components located on the side of the transmitting circuit board 200 facing the heat dissipation housing 400, preventing the support portion 310 from pressing against the electronic components. Furthermore, the hollow structure of the third through hole 313 reduces the weight of the bracket and, consequently, the weight of the transmitting module. The first upright post 321, second upright post 322, first reinforcing rib 331, and second reinforcing rib 332 are all located on the side of the support portion 310 away from the transmitting circuit board 200. The first upright post 321 extends from one end of the edge of the third through hole 313, and the second upright post 322 extends from the other end of the edge of the third through hole 313. Each end of the reinforcing ribs is fixedly connected to the first upright post 321 and the second upright post 322, respectively.

On one hand, the reinforcing ribs enhance the deformation resistance of the bracket 300, thereby strengthening its support and protection for the transmitting circuit board 200. On the other hand, the first upright post 321 and the second upright post 322 increase the distance between the two reinforcing ribs and the transmitting circuit board 200, thereby avoiding interference with electronic components mounted on the side of the transmitting circuit board 200 facing the heat dissipation housing 400 and preventing the reinforcing ribs from pressing against these components during installation.

In one embodiment, the first upright post 321, second upright post 322, first reinforcing rib 331, and second reinforcing rib 332 collectively enclose a first through hole 333. The first boss 410 on the heat dissipation housing 400 passes through the first through hole 333 and abuts the heat dissipation pad 600, which is located between the first boss 410 and the transmitting circuit board 200. That is, the heat dissipation pad 600 is located on one side of the transmitting circuit board 200 (the side facing the heat dissipation housing 400), while each transmitting unit on the transmitting circuit board 200 is fixedly mounted on the other side (the side facing the transmitting lens barrel 100). Partial heat generated by each transmitting unit during operation is exchanged via the heat dissipation pad 600 and the first boss 410, and then the heat is conducted and dispersed to other surfaces of the heat dissipation housing 400 via the first boss 410. This enhances the thermal conduction effect of the heat dissipation housing 400 on the transmitting circuit board 200 and improves the heat dissipation performance of the transmitting module.

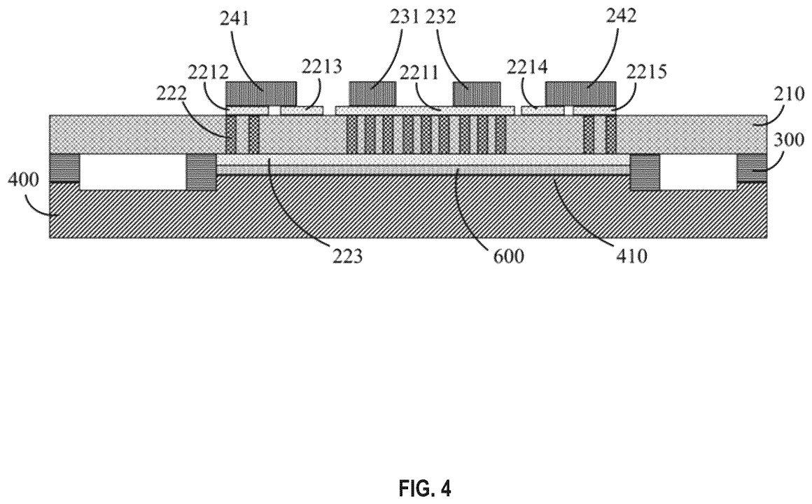

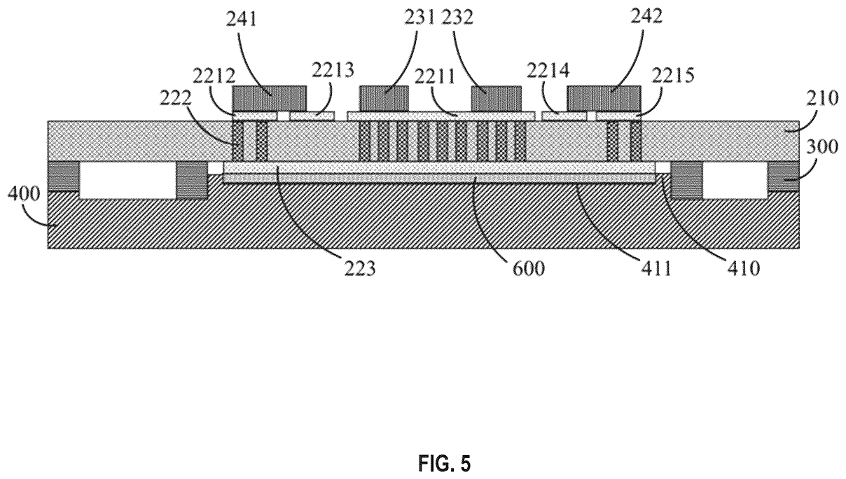

In one embodiment, as shown in FIGS. 4 and 5, the transmitting circuit board 200 includes a substrate 210, a first transmitting unit 231, a second transmitting unit 232, a first driving unit 241, a second driving unit 242, and electrical connection components. Among these, the first driving unit 241 is configured to drive the first transmitting unit 231 to emit pulsed laser light, and the second driving unit 242 is configured to drive the second transmitting unit 232 to emit pulsed laser light. The electrical connection components are used for electrical interconnection between the elements on the transmitting circuit board 200.

In one embodiment, as shown in FIG. 4, the electrical connection components include a first top copper layer 2211, a second top copper layer 2212, a third top copper layer 2213, a fourth top copper layer 2214, a fifth top copper layer 2215, copper columns 222, a bottom copper layer 223, and metal wires (not shown). The first transmitting unit 231, second transmitting unit 232, first driving unit 241, and second driving unit 242 are all arranged on the side of the substrate 210 facing the transmitting lens barrel 100. The bottom copper layer 223 is arranged on the side of the substrate 210 facing the heat dissipation housing 400. Both the first transmitting unit 231 and the second transmitting unit 232 are connected to the first top copper layer 2211. One end of the first top copper layer 2211 is located between the first transmitting unit 231 and the substrate 210, and the other end is located between the second transmitting unit 232 and the substrate 210. The second top copper layer 2212 is located between a first end of the first driving unit 241 and the substrate 210. The third top copper layer 2213 is located between a second end of the first driving unit 241 and the substrate 210. The fourth top copper layer 2214 is located between a first end of the second driving unit 242 and the substrate 210. The fifth top copper layer 2215 is located between a second end of the second driving unit 242 and the substrate 210. The bottom copper layer 223 is located between the substrate 210 and the heat dissipation pad 600. The heat dissipation pad 600 is located between the bottom copper layer 223 and the first boss 410.

In one embodiment, the substrate 210 is provided with multiple second through holes. Copper columns 222 are embedded in the second through holes, with each second through hole corresponding to one copper column 222. The transmitting module includes a first group of copper columns, a second group of copper columns, and a third group of copper columns. The first group of copper columns is located between the first top copper layer 2211 and the bottom copper layer 223, and includes multiple copper columns 222. The second group of copper columns is located between the second top copper layer 2212 and the bottom copper layer 223, and includes multiple copper columns 222. The third group of copper columns is located between the fifth top copper layer 2215 and the bottom copper layer 223, and includes multiple copper columns 222. For the multiple copper columns 222 within the first group, one end of each copper column 222 abuts the first top copper layer 2211, and the other end abuts the bottom copper layer 223, achieving electrical connection between the first top copper layer 2211 and the bottom copper layer 223. For the multiple copper columns 222 within the second group, one end of each copper column 222 abuts the second top copper layer 2212, and the other end abuts the bottom copper layer 223, achieving electrical connection between the second top copper layer 2212 and the bottom copper layer 223. For the multiple copper columns 222 within the third group, one end of each copper column 222 abuts the fifth top copper layer 2215, and the other end abuts the bottom copper layer 223, achieving electrical connection between the fifth top copper layer 2215 and the bottom copper layer 223. No second through holes or copper columns 222 are provided between the third top copper layer 2213 and the bottom copper layer 223, and no second through holes or copper columns 222 are provided between the fourth top copper layer 2214 and the bottom copper layer 223. This configuration ensures the normal operation of the current circuit.

In one embodiment, taking the first transmitting unit 231 and the first driving unit 241 as an example to illustrate the composition of the emission current loop, the driving current corresponding to the first transmitting unit 231 sequentially passes through the first end of the first driving unit 241, the second top copper layer 2212, the multiple copper columns 222 within the second group of copper columns, the bottom copper layer 223, the multiple copper columns 222 within the first group of copper columns, the first top copper layer 2211, the first transmitting unit 231, and a metal wire before returning to the second end of the first driving unit 241. Among these, the first transmitting unit 231 and the second end of the first driving unit 241 are electrically connected via the metal wire. The first end and the second end of the first driving unit 241 are electrically connected, forming a complete emission current loop to supply the first transmitting unit 231 for pulsed laser emission.

In one embodiment, referring to FIG. 4, after the heat dissipation housing 400, the bracket 300, and the transmitting circuit board 200 are fixedly connected, the first boss 410 passes through the first through hole 333 and abuts the heat dissipation pad 600. The heat dissipation pad 600 is pressed against the bottom copper layer 223 by the first boss 410 during assembly, or the heat dissipation pad 600 is bonded to the bottom copper layer 223 using conductive adhesive. As shown in FIG. 5, differing from the structure of the transmitting module in FIG. 4, the first boss 410 is also provided with a first mounting groove 411. The shape of the groove of the first mounting groove 411 is adapted to the heat dissipation pad 600. The heat dissipation pad 600 is embedded and installed in the first mounting groove 411 and abuts the bottom copper layer 223. The thickness of the heat dissipation pad 600 is equal to or approximately equal to the height of the groove of the first mounting groove 411. Embedding the heat dissipation pad 600 in the groove of the first mounting groove 411 facilitates the release of stress generated by the heat dissipation pad 600 during temperature changes. Moreover, the wall of the groove of the first mounting groove 411 can restrict the deformation and displacement of the heat dissipation pad 600. Simultaneously, it can increase the contact area between the heat dissipation pad 600 and the surface of the first boss 410, enhancing the heat dissipation performance of the transmitting module.

In another embodiment, a second mounting groove is provided on the substrate 210. The bottom of the second mounting groove is connected to each second through hole. Both the bottom copper layer 223 and the heat dissipation pad 600 are embedded and installed in the second mounting groove, with the bottom copper layer 223 located between the bottom wall of the second mounting groove and the heat dissipation pad 600. The provision of the second mounting groove effectively protects the bottom copper layer 223 and restricts the movement of the heat dissipation pad 600, preventing relative displacement between the bottom copper layer 223 and the heat dissipation pad 600. This ensures effective contact between the heat dissipation pad 600 and the bottom copper layer 223, preventing any impact on the heat dissipation from the bottom copper layer 223 to the heat dissipation pad 600.

In another embodiment, the first boss 410 is provided with a first mounting groove 411, and the substrate 210 is provided with a second mounting groove. The bottom copper layer 223 is embedded and installed in the second mounting groove, and the heat dissipation pad 600 is embedded and installed in the first mounting groove 411. The provision of multiple mounting grooves can better restrict relative displacement between the bottom copper layer 223 and the heat dissipation pad 600, ensuring the heat conduction effect between them.

During the emission of high-frequency pulsed laser light by each transmitting unit, both the transmitting unit itself and its corresponding driving unit generate significant heat. Establishing efficient heat conduction paths is a critical factor affecting the thermal performance of the transmitting module. With reference to FIGS. 1-5, the overall heat conduction path of the transmitting module is described as follows: the substrate 210 can conduct part of the heat generated by electronic components mounted on it to the surface of the heat dissipation housing 400 via the support portion 310, and then conduct it to the housing of the LiDAR via the surface of the heat dissipation housing 400.

Furthermore, taking the first transmitting unit 231 and the first driving unit 241 as an example, heat generated by the first transmitting unit 231 can be transferred to the first group of copper columns via the first top copper layer 2211. The first group of copper columns conducts the heat to the bottom copper layer 223, which in turn conducts it to the heat dissipation pad 600. Heat generated by the first driving unit 241 can be transferred to the second group of copper columns via the second top copper layer 2212. The second group of copper columns conducts the heat to the bottom copper layer 223, which then conducts it to the heat dissipation pad 600. The heat dissipation pad 600 disperses the heat conducted from the bottom copper layer 223 to the surface of the first boss 410. The first boss 410 then disperses the heat to other surfaces of the heat dissipation housing 400 for heat exchange with the LiDAR housing or the external environment. The provision of multiple copper columns 222 effectively increases the heat dissipation area. Therefore, the multiple top copper layers, the bottom copper layer 223, and the multiple copper columns 222 within the electrical connection components not only serve for current transmission but also act as part of the heat conduction path, enhancing the heat dissipation performance of the transmitting module.

In one embodiment, the contact area between the bottom copper layer 223 and the substrate 210 is larger than the contact area between the first top copper layer 2211 and the substrate 210. The contact area between the heat dissipation pad 600 and the first boss 410 is greater than or equal to the contact area between the bottom copper layer 223 and the heat dissipation pad 600. By establishing progressively increasing contact areas along the heat conduction path, the effective heat dissipation area is gradually enlarged, thereby enhancing the heat dissipation performance of the transmitting module and improving the operational stability of the LiDAR.

In some embodiments, the material of the heat dissipation pad 600 includes one or a combination of thermally conductive silicone, gold, silver, copper alloy, aluminum alloy, graphene, diamond, or carbon nanotubes. In one embodiment, the material of the heat dissipation pad 600 is one of graphene, diamond, or carbon nanotubes. Materials like graphene, diamond, and carbon nanotubes have higher thermal conductivity coefficients than common thermal conductors like copper, aluminum, or silicone, effectively dispersing the heat conducted from the bottom copper layer 223 to the first boss 410.

In one embodiment, the coefficient of thermal expansion (CTE) of the heat dissipation pad 600 material is equal to or approximately equal to the CTE of the substrate 210 material or the CTE of the bottom copper layer 223 material. Since the heat dissipation pad 600 abuts the bottom copper layer 223, a significant difference in their deformation during temperature changes can cause partial separation of the contact surfaces, thereby affecting the thermal conduction between them and the heat dissipation performance of the module. By appropriately setting the coefficient of thermal expansion of the heat dissipation pad 600, the problem of differential deformation caused by temperature changes can be effectively resolved, thereby ensuring the heat dissipation effect of the heat dissipation pad 600.

In one embodiment, the CTE of the material of the support portion 310 is equal to or approximately equal to the CTE of the heat dissipation housing 400. This reduces the difference in deformation between the support portion 310 and the heat dissipation housing 400 during temperature changes, ensuring the structural stability of the support portion 310. Consequently, it prevents excessive deformation differences from affecting the support and protection provided by the bracket 300 to the transmitting circuit board 200.

In one embodiment, the present application discloses a LiDAR. The LiDAR includes a receiving module, a processor, and the transmitting module according to any of the preceding embodiments. Among these, the transmitting lens barrel 100 within the transmitting module further contains multiple transmitting lenses, and the multiple transmitting units on the transmitting circuit board 200 form a transmitting array. Scanning beams emitted by the transmitting array are transmitted via the multiple transmitting lenses toward a detection area. Targets within the detection area reflect the scanning beams to form echo beams. The receiving module receives the echo beams to obtain echo signals. The processor processes the echo signals to derive measurement parameters of the targets, such as shape, distance, velocity, and surface reflectivity.

In one embodiment, the LiDAR is one of a mechanical LiDAR, an Optical Phased Array (OPA) solid-state LiDAR, a Micro Electromechanical System (MEMS) solid-state LiDAR, or a Flash solid-state LiDAR. The processor can be a Field-Programmable Gate Array (FPGA), System on Chip (SoC), Central Processor Unit (CPU), Network Processor (NP), digital signal processing circuit, Micro Controller Unit (MCU), Application-Specific Integrated Circuit (ASIC), or any combination thereof, used to implement the relevant functions. The transmitting array is a two-dimensional array or a one-dimensional linear array. Each transmitting unit is one of a laser diode, a Vertical-Cavity Surface-Emitting Laser (VCSEL), or an Edge-Emitting Laser (EEL). In one embodiment, the first transmitting unit 231 and the second transmitting unit 232 are in the same column or the same row of a two-dimensional array. Alternatively, the first transmitting unit 231 and the second transmitting unit 232 are on the same one-dimensional linear array.

The present application discloses a transmitting module and a LiDAR. The electrical connection components within the transmitting circuit board 200, such as the top copper layers, copper columns, and bottom copper layer, serve the dual composite functions of electrical conduction and heat transfer, effectively enhancing the heat dissipation performance of the transmitting module. The bracket 300 arranged between the transmitting circuit board 200 and the heat dissipation housing 400 supports and protects the transmitting circuit board 200, reducing the impact of deformation caused by structural stress, vibration, or temperature changes on its structural stability. Furthermore, the bracket 300 can also conduct and disperse heat generated on the transmitting circuit board 200 to the heat dissipation housing 400. The provision of the first through hole 333 on the bracket 300 allows the first boss 410 on the heat dissipation housing 400 to directly abut the heat dissipation pad 600. This effectively enhances the thermal conduction effect of the heat dissipation housing 400 on the heat generated by the electronic components on the transmitting circuit board 200, improving the heat dissipation performance of the transmitting module and the operational stability of its electronic components, thereby enhancing the operational stability of the LiDAR.

What is claimed is:

1. A transmitting module, comprising a transmitting lens barrel, a transmitting circuit board, a bracket, a heat dissipation housing, and a heat dissipation pad,
wherein the transmitting circuit board is located between the transmitting lens barrel and the bracket, and the bracket is located between the transmitting circuit board and the heat dissipation housing;
wherein the bracket comprises a first through hole, and the heat dissipation housing comprises a first boss; and
wherein the first boss passes through the first through hole and abuts against the heat dissipation pad, and the heat dissipation pad is located between the first boss and the transmitting circuit board.

2. The transmitting module according to claim 1, wherein the transmitting circuit board comprises a first transmitting unit, a second transmitting unit, a first top copper layer, a substrate, and a bottom copper layer; and
wherein the substrate is located between the first top copper layer and the bottom copper layer, the first top copper layer is connected to the first transmitting unit, the first top copper layer is connected to the second transmitting unit, and the bottom copper layer is located between the substrate and the heat dissipation pad.

3. The transmitting module according to claim 2, wherein the transmitting circuit board further comprises a plurality of copper columns, and the substrate comprises a plurality of second through holes; and
wherein one of the copper columns is embedded in one of the second through holes.

4. The transmitting module according to claim 3, wherein one end of each copper column abuts against the first top copper layer, and the other end of each copper column abuts against the bottom copper layer.

5. The transmitting module according to claim 2, wherein a contact area between the heat dissipation pad and the first boss is greater than or equal to a contact area between the heat dissipation pad and the bottom copper layer.

6. The transmitting module according to claim 2, wherein a coefficient of thermal expansion of a material of the heat dissipation pad is equal to a coefficient of thermal expansion of a material of the bottom copper layer.

7. The transmitting module according to claim 1, wherein the bracket comprises a support portion, a first upright post, a second upright post, a first reinforcing rib, and a second reinforcing rib,
wherein the support portion is located between the heat dissipation housing and the transmitting circuit board; and
wherein the first upright post is disposed at one end of the support portion, and the second upright post is disposed at the other end of the support portion, wherein the first upright post, the second upright post, the first reinforcing rib, and the second reinforcing rib collectively enclose to form the first through hole.

8. The transmitting module according to claim 7, wherein a coefficient of thermal expansion of a material of the support portion is equal to a coefficient of thermal expansion of a material of the heat dissipation housing.

9. The transmitting module according to claim 1, wherein the first boss comprises a first mounting groove, wherein the heat dissipation pad is embedded in the first mounting groove.

10. A LiDAR, comprising a receiving module, a processor, and the transmitting module according to claim 1.
